(19) United States
(12) Patent Application Publication
(10) Pub. No.: US 2012/0168221 A1
(43) Pub. Date: Jul. 5, 2012

(54) RELAY BOARD FOR TRANSMISSION CONNECTOR USE

(75) Inventors: Takeshi Okuyama, Shinagawa (JP); Tohru Yamakami, Shinagawa (JP)

(73) Assignee: FUJITSU COMPONENT LIMITED, Tokyo (JP)

(21) Appl. No.: 13/343,450

(22) Filed: Jan. 4, 2012

(30) Foreign Application Priority Data
Jan. 5, 2011 (JP) 2011-000651

(51) Int. Cl. H05K 1/11

(52) U.S. Cl. 174/264; 174/266

(57) ABSTRACT

A relay board for relaying plurality of electric wires to a transmission connector, the relay board provided with first and second front ground pads 12a, 12b which are arranged on a front surface, first and second back ground pads 13a, 13b which are arranged on a back surface, signal pads 14a to 15b which are arranged between the ground pads, a first via hole 17a which connected the first front ground pad 12a and the first back ground pad 13a, and a second via holes 17b which connects the second front ground pad 12b and second back ground pad 13b, the first via hole 17a and the second via hole 17b being arranged at the both sides of the signal pads. It is possible to provide an inexpensive relay board with excellent transmission characteristics and grounding characteristics.

### BACKGROUND OF THE INVENTION

1. Field of the Invention

The present invention relates to a relay board for transmission connector use.

2. Description of the Related Art

Relay boards and other printed circuit boards sometimes for example have front surface conductor patterns and back surface conductor patterns electrically connected by via holes which are formed by plating through holes. Usually, via holes which are formed on the pad surfaces of a printed circuit board are plugged. As known methods of plugging the via holes, there is the method of forming via holes in the printed circuit board, plating them, plugging the via holes which are formed on the pad surfaces by a resin, etc., then plating the via holes on the pad surfaces, coating the entire surface of the printed circuit board with a solder resist, exposing the required parts to UV light to cause them to cure, then dissolving the unnecessary parts of the solder resist by an alkali.

For example, Japanese Patent Publication (A) No. 2001-111213 describes a method of plugging the via holes, in which has solder resist been inserted into the through holes by using the printing method, using heat to make the solvent evaporate, then pressing to flatten the built up parts of the solder resist, exposing the necessary parts to UV light, removing the uncured parts of the solder resist, and using heating to cause complete curing and secure a uniform surface.

### SUMMARY OF THE INVENTION

In a relay board used for a transmission connector, it is necessary to plug the via holes and to obtain high impedance matching in order to raise the transmission characteristics.

The present invention provides a relay board for transmission connector use which has high transmission characteristics and grounding characteristics and is low in cost.

One aspect of the present invention is a relay board for relaying a plurality of electric wires to a transmission connector, the relay board is provided with first and second front ground pads arranged on a front surface of an end part of the relay board, the first and second front ground pads adapted to be connected to electric wires, first and second back ground pads arranged on a back surface of the end part of the relay board and beneath the first and second front ground pads, respectively, the first and second back ground pads adapted to be connected to electric wires, a signal pad arranged between the first and second front ground pads or between the first and second back ground pads, the signal pad adapted to be and which connected to an electric wire, a first via hole connecting the first front ground pad to the first back ground pad, and a second via hole connecting the second front ground pad to the second back ground pad, the first via hole and the second via hole are arranged at both sides of the signal pad.

The first and second via holes may be formed at end parts, positioned close to a side face of relay board, of the first and second front ground pads and the first and second back ground pads.

The first and second via holes may be plugged using a resist.

A connection region adapted to be connected to an electric wire and a region covered by the resist may be formed on each of the first and second front ground pads and/or each of the first and second back ground pads, respectively.

According to the present invention, via holes which connect front surface ground pads and back surface ground pads are arranged at the both sides of the signal pads on the relay board, so it is possible to obtain a high impedance matching and secure high transmission characteristics. Further, when the relay board is a multilayer printed circuit board which has ground layers (inner ground layers), since the via holes are formed at the end parts of the ground pads at positions closer to the side face of the relay board, it is possible to prevent the occurrence of stubs in the transmission paths in the ground layers and it is possible to obtain good grounding characteristics. More specifically, for pads on the relay board, for example, in the case of balanced transmission, the pads are arranged in the order of ground, signal (+), signal (−), ground, signal (+), signal (−), ground . . . , that is, the signal pads are surrounded by ground pads, so the signal and ground pads are matched in impedance across the entire length of the transmission path. Further, the via holes which connect the ground pads and the ground layers are arranged near the signal pads, so it is possible to obtain more advanced impedance matching and possible to secure high transmission characteristics.

### BRIEF DESCRIPTION OF THE DRAWINGS

These object, features, and advantages and other objects, features, and advantages of the present invention will become clearer from the following detailed description of preferred embodiments of the present invention which are illustrated in the attached drawings, in which:

FIG. 1 is a perspective view of a relay board of the present embodiment which is applied to a high speed transmission connector,

FIG. 2 is a partial enlarged perspective view which enlarges a part of the relay board of the present embodiment,

FIG. 3 is a cross-sectional view of a relay board along the line III-III of FIG. 1,

FIG. 4 is a cross-sectional view of a relay board along the line IV-IV of FIG. 1,

### DESCRIPTION OF THE PREFERRED EMBODIMENTS

Below, embodiments of the present invention will be explained in detail with reference to the attached drawings. Further, in the following embodiments, same or similar component elements are shown with common reference notations.

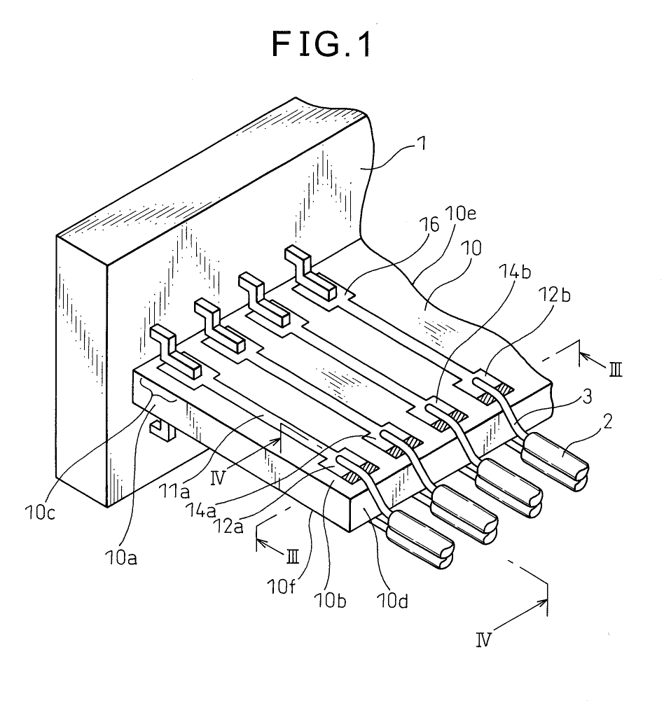

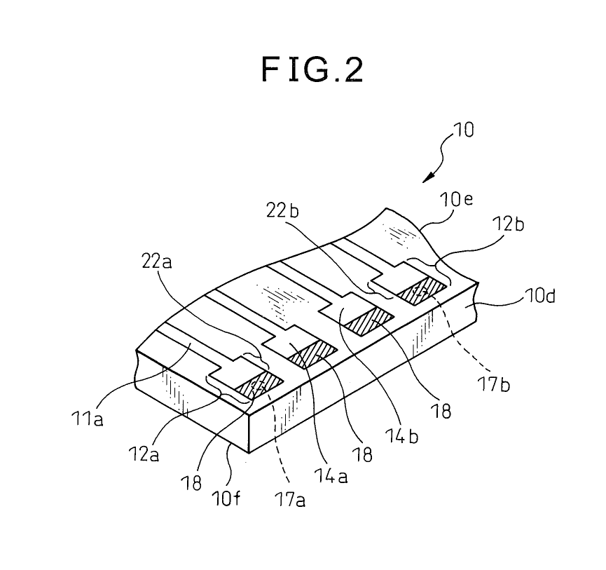

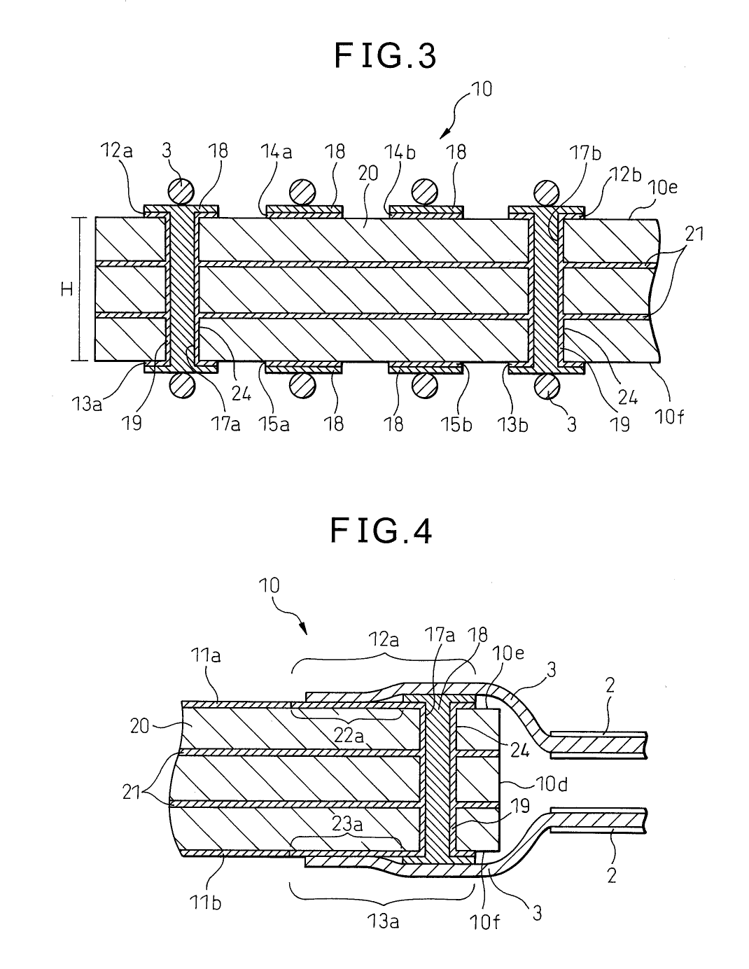

FIG. 1 is a perspective view of a relay board 10 of the present embodiment which is applied to a high speed transmission connector 1, FIG. 2 is a partial enlarged perspective view which enlarges part of the relay board 10, FIG. 3 is a cross-sectional view of a relay board 10 along the line of FIG. 1, and FIG. 4 is a cross-sectional view of a relay board 10 along the line IV-IV of FIG. 1. These figures show the structure of an end part of the relay board 10. As shown in FIG. 1, the relay board 10 is a tabular member having a front surface 10e and a back surface 10f, and at the front surface 10e of the relay board 10, four conductor patterns 11a are arranged for connecting cables 2 and a high speed transmission connector 1. In the same way as the front surface 10e, at the back surface 10f of the relay board 10, four conductor patterns lib are arranged (see FIG. 4). At first end parts of the conductor patterns 11a of the front surface 10e, wire-side pads 12a, 12b, 14a, and 14b are formed for connection with the electric wires 3 which extend from the cables 2. At the other end parts, connector-side pads 16 are formed for connection with the high speed transmission connector 1. At the conductor patterns lib of the back surface 10f as well, at first end parts, wire-side pads 13a, 13b, 15a, and 15b are formed for connection with the electric wires 3 (see FIG. 3), while at the other end parts, connector-side pads (not shown) are formed for connection with the high speed connector 1. The relay board 10, as shown in FIG. 3 and FIG. 4, is a multilayer printed circuit board which has ground layers 21 (inner ground layers) and comprises a front surface layer (conductor patterns 11a), intermediate layers (ground layers 21), and a back surface layer (conductor patterns 11b) which are laminated with sandwiching a plurality of insulating board 20. The relay layer may not have ground layers 21.

The pads 12a to 15b which are arranged at the end part 10b of the relay board 10 will be explained in detail. The conductor patterns 11a which are arranged on the front surface 10e of the relay board 10 are formed with, at the end part 10b of the relay board 10, a first front ground pad 12a and a second front ground pad 12b and a first front signal pad (+) 14a over which a forward direction (plus direction) signal is sent and a second front signal pads (−) 14b over which a reverse direction (minus direction) signal is sent. The first front ground pad 12a and the second front ground pad 12b and the first front signal pad (+) 14a and the second front signal pad (−) 14b are electrically connected to wires 3 which extend from a plurality of cables 2. As shown in the figure, the first front signal pad 14a and the second front signal pad 14b are arranged between the first front ground pad 12a and the second front ground pad 12b. Further, the conductor patterns 11b which are arranged on the back surface 10f of the relay board 10 are formed with, at the end part 10b of the relay board 10, as shown in FIG. 3, a first back ground pad 13a and a second back ground pad 13b and a first back signal pad (+) 15a over which a forward direction signal is sent and a second back signal pad (−) 15b over which a reverse direction signal is sent. The first back signal pad 15a and the second back signal pad 15b are arranged between the first back ground pad 13a and the second back ground pad 13b. The wires 3 which extend from the plurality of cables 2 are connected by soldering to the above-mentioned first and second front ground pads 12a, 12b, first and second back ground pads 13a, 13b, first and second front signal pads 14a, 14b, and first and second back signal pads 15a, 15b (see FIG. 3 and FIG. 4). Note that, FIG. 1 to FIG. 4 only show one set of ground pads and signal pads on the relay board 10. In actually, a plurality of these sets are arranged in parallel on the relay board 10.

The relay board 10 of the present embodiment, as shown in FIG. 3 and FIG. 4, is a multilayer printed circuit board which a front surface layer (conductor patterns 11a), intermediate layers (ground layers 21), and a back surface layer (conductor patterns 11b) are laminated with sandwiching insulating boards 20. The insulating boards 20 are made of, for example, an epoxy resin, polyimide resin, etc. The thickness H of the relay board 10 is 0.5 mm to 2.5 mm or so. The relay board 10 of the present embodiment, as shown in FIG. 3, is formed with a first via hole 17a so as to extend from the first front ground pad 12a of the front surface layer through the ground layer 21 to the first back ground pad 13a of the back surface layer. Similarly, it is formed with a second via hole 17b so as to extend from the second front ground pad 12b through the ground layer 21 to the second back ground pad 13b. The first and second via holes 17a, 17b are usually fabricated by forming through holes 24 in the relay board 10 by drilling or a laser, then forming plating 19 on the surfaces of the through holes 24.

The positions of the first and second via holes 17a, 17b which are formed on the relay board 10 of the present embodiment will be explained next. The first and second via holes 17a, 17b are formed at the ground pads which connect to the electric wires 3 (first and second front ground pads 12a, 12b and first and second back ground pads 14a, 14b) which are positioned at the opposite side to the pads 16 which connect to the high speed transmission connector 1. Usually, if forming via holes, the via holes are plugged, but this plugging operation sometimes causes step differences to form on the pads.

These step differences can cause poor connection between the connector and the pads. In the present embodiment, the via holes are not formed at the connector-side pads 16 so as to secure flat connection regions 10c for connection with the high speed transmission connector 1 (also called “mounting areas”). Instead, to connect the front surface layer, intermediate layers, and back surface layer to obtain high transmission characteristics, first and second via holes 17a, 17b are formed at the ground pads at the sides connecting to the wires 3.

In the relay board 10 of the present embodiment, as explained above, the first via hole 17a is formed so as to connect the first front ground pad 12a and the first back ground pad 13a which is positioned below it. Further, the second via hole 17b is formed so as to connect the second front ground pad 12b and the second back ground pad 13b which is positioned below it. As a result, a pair of via holes 17a, 17b are arranged at the both sides of the first and second front signal pads 14a, 14b and the first and second back signal pads 15a, 15b. By arranging via holes at the both sides of the signal pads in this way, it is possible to provide a certain distance between the via holes and possible to obtain advanced impedance matching so as to secure high transmission characteristics of the relay board 10. Note that, the relay board 10 of the present embodiment is a relay board for high speed transmission connector use and has a total of four signal pads arranged at the back and front between the ground pads for balanced transmission. However, the arrangement of the signal pads is not limited to this. One or more signal pads may be arranged. Further, the signal pads may be arranged at just the front surface or back surface of the relay board 10.

Further, as will be understood from FIG. 2 and FIG. 4, the first via hole 17a is formed at the end parts of the first front ground pad 12a and the first back ground pad 13a positioned at the side face 10d of the relay board 10 of the side connecting to the electric wires 3. The side face 10d is opposite to the side face connecting to the high speed transmission connector 1. By forming the first via hole 17a in the ground pads at positions closer to the side face 10d of the relay board 10, for example, at the ground layers 21, the range of the branched state of the transmission path (stub) becomes narrower and better grounding characteristics can be obtained. Further, as will be understood from FIG. 2, the second via hole 17b, in the same way as the first via hole 17a, is formed on the second front ground pad 12b at the end part positioned closer to the side face 10d of the relay board 10, that is, at a position closer to the side face 10d of the relay board 10.

Further, as shown in FIG. 4, as explained above, the first via hole 17a is formed on the first front ground pad 12a and the first back ground pad 13a at positions close to the side face 10d, while the first front ground pad 12a and the first back ground pad 13a are provided with connection regions 22a, 23a for connection with the electric wires 3 (also called “mounting areas”). For this reason, the electric wires 3 are soldered to the connection regions 22a and 23a of the first front ground pad 12a and first back ground pad 13a across the top end or the bottom end of the first via hole 17a. Similarly, the second front ground pad 12b and second back ground pad 13b are also formed with connection regions 22b (see FIG. 2), 23b (not shown) for connection with the electric wires 3. The electric wires 3 are soldered to the connection regions 22b and 23b of the second front ground pad 12b and second back ground pad 13b across the top end or the bottom end of the second via hole 17b.

Next, the plugging operation of the first and second via holes 17a, 17b will be explained. In the present embodiment, as shown in FIG. 3 and FIG. 4, the first and second via holes 17a, 17b are plugged using a resist 18. As explained above, the first front ground pad 12a and the wires 3 are connected by soldering. However, if this soldering is performed in the state where the first via hole 17a is not plugged, sometimes the first via hole 17a will suck in the solder and solder will flow out to the opposite side back surface layer. Such a phenomenon leads to an insufficient or excessive amount of solder and instability in the amount of solder. For this reason, in the past, the holes of the via holes have been plugged with a resin. Further, to prevent hindering connection to the via holes by the plugged resin, the top ends and the bottom ends of the plugged via holes have been further plated.

However, the conventional method is costly in terms of the plating materials and the processing costs, so to keep manufacturing costs down, sometimes the via holes have not been provided on the pads at the sacrifice of the transmission characteristics. In the present embodiment, as shown in FIG. 4, the wires 3 are soldered to the connection regions 22a, 23a straddling the top end and bottom end of the first via hole 17a to thereby secure electrical connection with the conductor patterns 11a, so the top end and the bottom end of the plugged via hole do not have to be plated like in the past. For this reason, in the present embodiment, only the resist 18 is used for plugging the via holes. Since no plating is provided, the plugging operation can be performed at a low cost and a relay board having via holes and high transmission characteristics can be inexpensively fabricated. Further, the wires 3 are soldered to the connection regions 22a, 23a straddling the top end and the bottom end of the first via hole 17a, so the surface of the printed circuit board need not be made a uniform surface like with the plugging method disclosed in Japanese Patent Publication (A) No. 2001-111213. Note that, a similar plugging operation using the resist 18 is also performed on the second via hole 17b formed at the second front ground pad 12b and second back ground pad 13b.

The resist is for example an insulator which is coated on the printed circuit board. In the present embodiment, to automatically plug the via holes, a light curing solder resist is used. The plugging operation using this resist is performed for example as follows: First, a through hole is formed using a drill or laser etc. so as to connect the first front ground pad 12a and the first back ground pad 13a. Further, the surface of the through hole is given a plating 19 to form the first via hole 17a. Further, the first via hole 17a is filled by coating a resist 18 at the end part 10b of the relay board 10. After this, the necessary parts are exposed to UV light to make them cure and the unnecessary parts of the resist are dissolved away by an alkali.

The first and second via holes 17a, 17b are arranged at the end part 10b of the relay board 10, so even without coating the entire surface of the relay board 10 with a resist, that is, by just coating the end part 10b of the relay board 10 with a resist, it is possible to plug the first and second via holes 17a, 17b at one time and possible to secure connection regions for connecting the wires 3 to the ground pads. The plugged first and second via holes 17a, 17b are not plated on their surfaces, so compared with when plating them, the plugging operation can be performed less expensively. Note that, as shown in FIG. 2 or FIG. 3, in the present embodiment, due to automation of the plugging operation, parts of the signal pads (14a, 14b, 15a, 15b) are coated with and have residual resist 18, but the resist 18 on the signal pads may be removed by an alkali etc.

Above, the present embodiment was explained using the attached drawings. It is possible to secure high transmission characteristics if forming via holes at the both sides of the signal pads like in the relay board according to the present invention. If forming via holes on the ground pads at the end parts positioned at the side face of the relay board, it becomes possible to prevent the occurrence of stubs and to obtain good grounding characteristics. Further, if securing connection regions on the ground pads and plugging the via holes with a resist, there is no need for plating, the relay board can be inexpensively produced, and in turn the production costs of high speed transmission connectors and other products in which relay boards are used can be lowered. Further, if forming the via holes at the pads which connect with the wires etc. positioned at the opposite side to the pads which connect with the connector like in the relay board according to the present invention, the connection regions which connect with the connector will never be intruded upon. Note that, to perform the plugging operation inexpensively, the plating treatment is omitted, but to secure reliable connection between the cables and pads, it is also possible to plate the top ends or the bottom ends of the via holes.

Representative embodiments were used to explain the present invention, but a person skilled in the art would be able to understand that the above changes and various other changes, deletions, and additions may be made without departing from the scope of the present invention.

1. A relay board for relaying a plurality of electric wires to a transmission connector, comprising:
first and second front ground pads arranged on a front surface of an end part of the relay board, the first and second front ground pads adapted to be connected to electric wires;
first and second back ground pads arranged on a back surface of the end part of the relay board and beneath the first and second front ground pads, respectively, the first and second back ground pads adapted to be connected to electric wires;
a signal pad arranged between the first and second front ground pads or between the first and second back ground pads, the signal pad adapted to be connected to an electric wire;
a first via hole connecting the first front ground pad to the first back ground pad; and
a second via hole connecting the second front ground pad to the second back ground pad,
wherein the first via hole and the second via hole are arranged at both sides of the signal pad.

2. The relay board of claim 1, wherein the first and second via holes are formed at end parts, positioned close to a side face of the relay board, of the first and second front ground pads and the first and second back ground pads.

3. The relay board of claim 2, wherein the first and second via holes are plugged using a resist.

4. The relay board of claim 3, wherein a connection region adapted to be connected to an electric wire and a region covered by the resist are formed on each of the first and second front ground pads and/or each of the first and second back ground pads, respectively.

5. The relay board of claim 1, wherein the first and second via holes are plugged using a resist.
